(19) United States
(12) Patent Application Publication
(10) Pub. No.: US 2011/0169004 A1
(43) Pub. Date: Jul. 14, 2011

(54) DISPLAY DEVICE AND MANUFACTURING METHOD THEREFOR

(75) Inventors: Shigeyuki Yamada, Osaka (JP); Daisuke Fuse, Osaka (JP)

(73) Assignee: SHARP KABUSHIKI KAISHA, Osaka (JP)

(21) Appl. No.: 13/054,790

(22) PCT Filed: Jun. 8, 2009
(86) PCT No.: PCT/JP2009/002579

§ 371 Date: Jan. 18, 2011

(30) Foreign Application Priority Data
Sep. 8, 2008 (JP) 2008-229884

(51) Int. Cl. H01L 33/08; H01L 33/36

(52) U.S. Cl. 257/59; 438/34; 257/E33.062; 257/E33.053

(57) ABSTRACT

An active matrix substrate of a display device of the present invention comprises a glass substrate, a plurality of connection terminals (41) formed on the surface of the glass substrate and arranged in parallel with one another at an equal interval, and an interlayer insulating film (38) covering the plurality of connection terminals. The edge of the interlayer insulating film is so formed that tips of the plurality of connection terminals are exposed. A notch (42) is formed along the edge of the interlayer insulating film between two adjacent connection terminals. The notch has a stepped portion (46) comprising the first face (43), which is the bottom face of the notch, the second face (44), which is at a higher level than the first face, and a sloped face (45), which continues from the first face to the second face. It is possible to avoid formation of pixel electrode material residue near the edge of the interlayer insulating film when a pixel electrode is formed by photo-etching through the formation of a pixel electrode material layer and a photosensitive resist layer on the interlayer insulating film.

### TECHNICAL FIELD

The present invention relates to a display device and a method for manufacturing the same.

### BACKGROUND ART

Display devices generally have a display panel in which a switching element substrate and an opposite substrate are bonded together to hold a display medium layer in between. In this configuration, the amount of light transmission is controlled by the difference in potential between the pixel electrode formed on the switching element substrate and the common electrode formed on the opposite substrate, and an image of particular gradations is displayed on a display screen accordingly.

In recent years, as switching element substrates, active matrix substrates having switching elements arranged in a matrix for respective pixels have widely been in use. These active matrix substrates generally have multiple connection terminals, which are arranged in parallel with each other and are respectively electrically connected to the switching elements for sending drive signals to the respective switching elements. Patent Documents 1 and 2 disclose structures adjacent to the connection terminals on active matrix substrates and manufacturing methods therefor.

### RELATED ART DOCUMENTS

### Patent Documents

Patent Document 1: Japanese Patent Application Laid-Open Publication No. H11-24101
Patent Document 2: Japanese Patent Application Laid-Open Publication No. H11-153809

### SUMMARY OF THE INVENTION

### Problems to be Solved by the Invention

Manufacturing method of conventional active matrix substrates, in particular, the connection terminal area, is described below with reference to FIG. 8 and FIG. 9. FIG. 8 is a plan view of a connection terminal area of an active matrix substrate. FIGS. 9 (a) to 9 (c) are cross-sectional views of the connection terminal area of the active matrix substrate in respective manufacturing steps. FIG. 9 (c) is a cross sectional view taken along the line I-I′ in FIG. 8.

In the manufacturing method of conventional active matrix substrates, first, multiple switching elements are arranged in a matrix over an insulating substrate 100. Then, a plurality of connection terminals 101 are formed for sending drive signals to the switching elements. The connection terminals 101 are respectively connected to the switching elements and are arranged in parallel with each other.

Next, an interlayer insulating film 102 is formed over the insulating substrate 100, on which switching elements and connection terminals 101 have been formed. The interlayer insulating film 102 is formed so that contact holes are formed to provide for connection to the switching elements and that tips of the connection terminals 101 are exposed.

Next, pixel electrode material 103 made of, for example, ITO (Indium Tin Oxide) is formed over the entire insulating substrate 100, on which interlayer insulating film 102 has been formed. Next, as shown in FIG. 9 (a), photosensitive resist 104 is applied on pixel electrode material 103, followed by exposure and development. Since the edge of interlayer insulating film 102 has a steep slope having an inclination angle of approximately 70°, the thickness (R2) of photosensitive resist 104 in the vicinity of the steep slope of the interlayer insulating film 102 is larger than the thickness (R1) of photosensitive resist 104 disposed over the interlayer insulating film 102 and is larger than the thickness (R3) of photosensitive resist 104 disposed over connection terminal 101 that extends towards the edge of insulating substrate 100.

Next, photosensitive resist 104 is subjected to exposure and development. However, since photosensitive resist 104 has an excessive thickness (R2) in the vicinity of the edge of interlayer insulating film 102 as described above, photosensitive resist 104 is not removed completely, leaving residue 104′ as shown in FIG. 9 (b).

Next, an etching process in which photosensitive resist 104 is used as a mask forms a pixel electrode of a predetermined pattern. Residue 104′ of photosensitive resist 104, which is left behind in the corner at the edge of interlayer insulating film 102, however, prevents a complete etching of the pixel electrode, leaving pixel electrode residue 105 as shown in FIG. 9 (c).

The presence of pixel electrode residue 105 near the edge of interlayer insulating film 102 causes electrical connection between pixel electrode residue 105 and neighboring connection terminals 101, as shown in FIG. 8. This electrical connection allows a leakage current between the terminals, resulting in display errors.

One solution to this problem is an increased exposure to eliminate any photosensitive resist residue. However, increased exposure excessively reduces the width of ITO lines, for example. Also, the increase in the exposure requires extended exposure time, which decreases the manufacturing efficiency.

The present invention was devised in consideration of the issues described above, and is aimed at providing a display device that has superior visual quality and that can be manufactured efficiently, and a manufacturing method thereof.

### Means of Solving the Problems

A display device of the present invention includes an active matrix substrate having a plurality of switching elements arranged in a matrix and an opposite substrate located opposite to the active matrix substrate through a display medium layer, wherein the active matrix substrate includes: a plurality of connection terminals for sending drive signals to the switching elements, wherein the connection terminals are respectively electrically connected to, and led out from, the switching elements and are arranged in parallel with each other; an interlayer insulating film disposed over the plurality of switching elements and over the plurality of connection terminals, wherein tips of the plurality of connection terminals along an edge of the interlayer insulating film are exposed; and a pixel electrode disposed on the interlayer insulating film and on an exposed region of the plurality of connection terminals, the pixel electrode being electrically connected to the switching element through a contact hole formed in the interlayer insulating film. The interlayer insulating film has a notch with a bottom face at an end of a region corresponding to a space between the plurality of connection terminals, and the interlayer insulating film has a stepped portion constituted of a first face constituting the bottom face of the notch, a second face, which is at a higher level than the first face and a sloped face that continues from the first face to the second face.

The shape of the first face of the interlayer insulating film of the display device of the present invention may be rectangular.

The height difference between the first face and the second face of the display device of the present invention may be 0.2 to 2.5 μm.

The length of the first face of the display device of the present invention in the extending direction of the connection terminals may be 4 μm or longer.

The display medium of the display device of the present invention may be constituted by a liquid crystal material.

The pixel electrode of the display device of the present invention may be made of indium tin oxide or indium zinc oxide.

The switching element of the display device of the present invention may be thin film transistors.

A manufacturing method for the display device of the present invention is a manufacturing method for a display device having an active matrix substrate, which has a plurality of switching elements arranged in a matrix and an opposite substrate located opposed to the active matrix substrate through a display medium layer, the method including the steps of: preparing an insulating substrate for the active matrix substrate; arranging a plurality of switching elements in matrix on the insulating substrate, and forming a plurality of connection terminals, which are arranged in parallel with each other and respectively electrically connected to, and led out from, the switching elements, for sending drive signals to the switching elements; forming an interlayer insulating material over the insulating substrate on which the switching elements and the connection terminals are disposed; forming an interlayer insulating film on a plurality of switching elements and on a plurality of connection terminals by subjecting the interlayer insulating material to exposure and development using a photomask having a plurality of recesses along an edge of the photomask, which recesses are arranged at a certain interval, wherein the interlayer insulating film has a contact hole leading to the switching element, exposes tips of the plurality of connection terminals along an edge of the interlayer insulating film, and has a notch with a bottom face at an end of a region corresponding to a space between the connection terminals, the interlayer insulating film having a stepped portion constituted of a first face constituting the bottom face of the notch, a second face, which is at a higher level than the first face, and a sloped face, which continues from the first face to the second face; forming an pixel electrode material over the insulating substrate on which the interlayer insulating film has been disposed; forming a photosensitive resist on the pixel electrode material and subjecting the resist to exposure and development; and forming a pixel electrode on the interlayer insulating film and on an exposed region of the plurality of connection terminals, the pixel electrode being electrically connected to the switching element through the contact hole formed in the interlayer insulating film, by an etching process in which the photosensitive resist is used as a mask.

### Effects of the Invention

The present invention provides a display device with a superior visual quality and an efficient manufacturing method of the same.

### BRIEF DESCRIPTION OF THE DRAWINGS

FIG. 1 is a cross-sectional view of a liquid crystal display device according to an embodiment of the present invention.

FIG. 2 is a cross-sectional view of a thin film transistor substrate according to an embodiment of the present invention.

FIG. 3 is a plan view of a thin film transistor substrate according to an embodiment of the present invention.

FIG. 4 is an isometric view of a thin film transistor substrate according to an embodiment of the present invention.

FIG. 5 is a cross-sectional view of an interlayer insulating film of a thin film transistor substrate according to an embodiment of the present invention.

FIG. 6 are plan views of a connection terminal region of thin film transistor substrate according to an embodiment of the present invention in respective manufacturing steps.

FIG. 7 is a plan view of a photomask having two rod portions according to an embodiment of the present invention and a plan view of the terminal region.

FIG. 8 is a plan view of a conventional active matrix substrate.

FIG. 9 are cross-sectional views of a connection terminal region of conventional active matrix substrate in respective manufacturing steps.

### DETAILED DESCRIPTION OF EMBODIMENTS

The structures of embodiments of the present invention and the manufacturing method of the same are described in detail below with reference to the figures. In the embodiments, a liquid crystal display device is used as an example of a display device. The present invention shall not be limited to the embodiments described below.

### Embodiments

(Structure of Liquid Crystal Display Device 10)

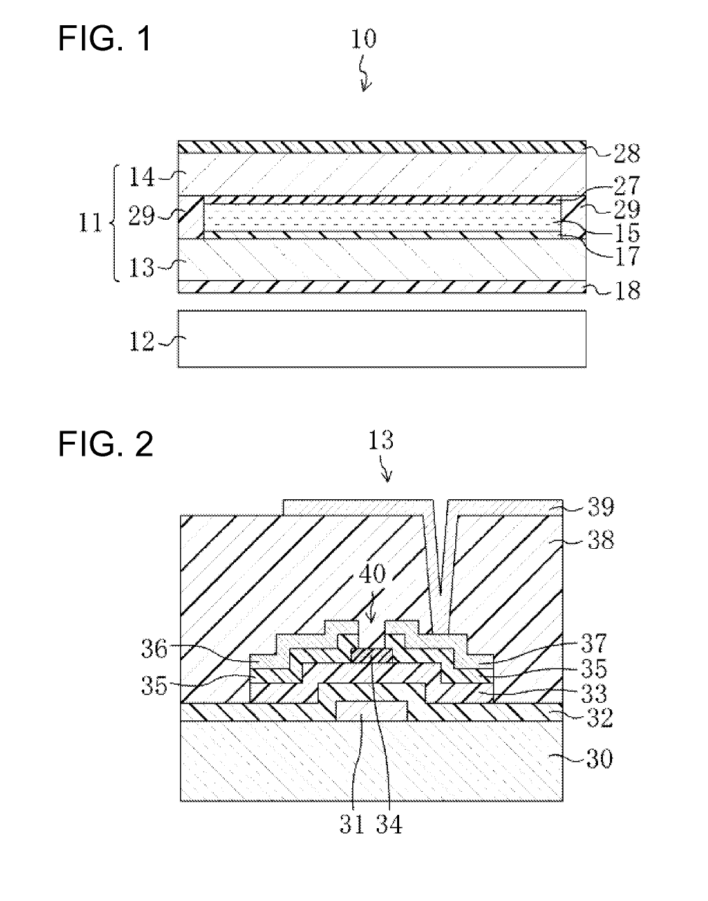

FIG. 1 is a cross-sectional view of a liquid crystal display device 10 according to an embodiment of the present invention. Liquid crystal display device 10 includes liquid crystal display panel 11 and backlight 12.

Liquid crystal display panel 11 includes a thin film transistor substrate 13 (active matrix substrate) in which polarizer 18 is located on the outer surface; a color filter substrate 14 (opposite substrate) in which polarizer 28 is located on the outer surface; and a liquid crystal layer 15 (display medium layer) located between the thin film transistor substrate 13 and the color filter substrate 14. Liquid crystal layer 15 is sealed in by sealing member 29 that bonds the thin film transistor substrate 13 and the color filter substrate 14 together.

On the glass substrate, which is the base material of color filter substrate 14, on the side facing liquid crystal layer 15, black matrix (light shield film, not shown), color filter (not shown), opposite electrode (not shown), and alignment film 27 are formed.

On thin film transistor substrate 13, a plurality of gate lines (not shown), which extend in the X axis direction, and a plurality of source lines (not shown), which extend in the Y axis direction, are formed. Each rectangle region laid out by the gate lines and source lines is a pixel region. Thin film transistor (switching element) 40 is formed at each intersection of the gate lines and the source lines. FIG. 2 is a cross-sectional view of thin film transistor 40 of thin film transistor substrate 13.

Thin film transistor substrate 13 has glass substrate 30 (insulating substrate) as the base. Instead of glass substrate 30, other kinds of material such as resin may be used as the insulating substrate. On glass substrate 30, gate electrodes 31 are formed. On gate electrode 31, gate insulating film 32 made of SiO₂ or SiN, for example, is formed. In certain regions of the gate insulating film 32, semiconductor film 33 (operating semiconductor film), which is an active layer of the thin film transistor 40, is formed. Semiconductor film 33 has a channel region, on which channel protecting film 34 made of an insulating material such as SiO₂ or SiN is formed. On the semiconductor film 33 and channel protective film 34, n⁺ semiconductor film 35 is formed. Over the n⁺ semiconductor film 35 including a portion covering channel protective film 34, source electrode 36 and drain electrode 37, both made of Al, Ta, MoW alloy or Cr, for example, are formed, wherein the source electrode 36 and the drain electrode 37 are apart from each other. Pixel electrode 39 disposed in a pixel region is electrically connected to drain electrode 37 through interlayer insulating film 38 made of an insulating material such as SiO₂ or SiN. Pixel electrode 39 is formed of a transparent conductive material such as ITO (Indium Tin Oxide) or IZO (Indium Zinc Oxide). On the pixel electrode 39, an alignment film 17, made of materials such as polyimide, is formed. On the edge of thin film transistor substrate 13, connection terminal 41, which is drawn from the source line, is formed for receiving external signals.

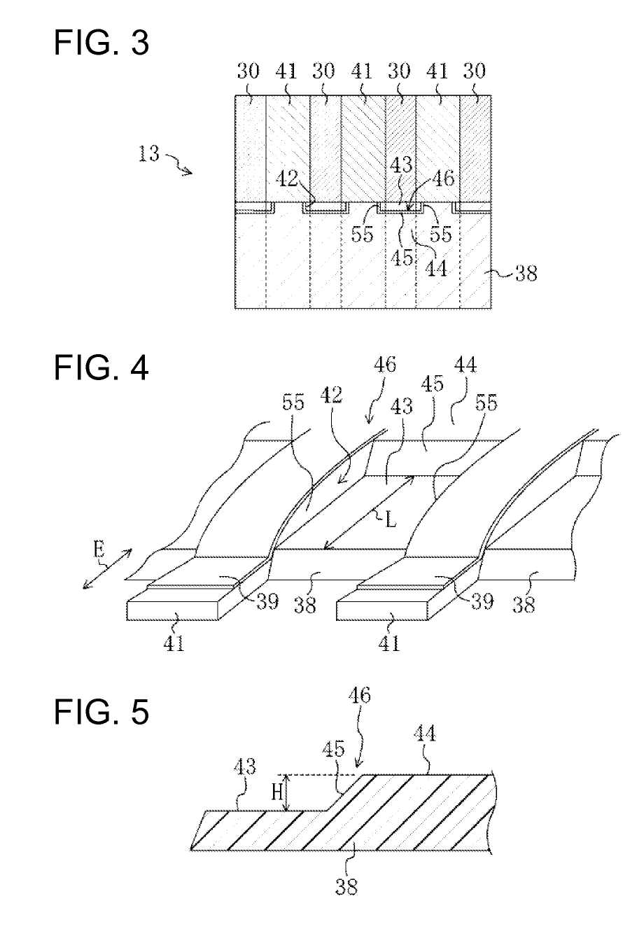

FIG. 3 is a plan view of the connection terminal 41 area of thin film transistor substrate 13. Note that pixel electrode 39 on connection terminal 41 is not shown in FIG. 3. FIG. 4 is an isometric view of the connection terminal 41 area of interlayer insulating film 38 of FIG. 3. As shown in FIG. 3 and FIG. 4, the connection terminal 41 area of thin film transistor substrate 13 has a plurality of connection terminals 41 formed on glass substrate 30, which are disposed in parallel with each other at an equal interval. Formed on the connection terminal 41 is interlayer insulating film 38, which is also formed on thin film transistor 40. The edge of interlayer insulating film 38 is so formed that tips of a plurality of connection terminals 41 are exposed. Pixel electrode 39, which is formed on interlayer insulating film 38, extends over the exposed tip of the connection terminal 41. In this embodiment, connection terminal 41 is an extension from the source line at the edge of thin film transistor substrate 13. Connection terminal 41, however, does not have to be an extension from the source line; it may be a terminal for the wiring drawn from the gate line.

Interlayer insulating film 38 has notches 42 along its edges, in the region corresponding to the space between adjacent connection terminals 41. Notch 42 has the rectangular-shaped first face 43 at the bottom. At the back of the first face 43 of interlayer insulating film 38, the second face 44 is formed at an elevated position. The second face 44 is the top surface of interlayer insulating film 38. Interlayer insulating film 38 also has gently-sloped face 45 that continues from the first face 43 to the second face 44. The first face 43, the second face 44 and the sloped face 45 constitute stepped portion 46 in interlayer insulating film 38. Interlayer insulating film 38 also has gently-sloped face 55 on both sides of the first face 43, continuing from the first face 43 to the top surface of the interlayer insulating film.

As shown in FIG. 5, the level difference H between the first face 43 and the second face 44 is preferably 0.2 to 2.5 μm. As shown in FIG. 4, distance L on the first face 43, which is along the extending direction E of connection terminal 41, is preferably 4.0 μm or longer.

The first face 43 of interlayer insulating film 38, which is the bottom face of notch 42, is not limited to a rectangle; it may be a triangle or other polygons. The first face 43 may also be a semicircle or semielliptical.

(Manufacturing Method of Liquid Crystal Display Device 10)

Liquid crystal display device 10 according to an embodiment of the present invention is described below. The manufacturing method described below is an example only. Liquid crystal display device 10 of the present invention shall not be limited to those manufactured by the method described below.

First, glass substrate 30, which is the base of thin film transistor substrate 13, is prepared. On the glass substrate 30, a metal film of, for example, A1 alloy, having a thickness of approximately 0.5 μm is deposited by sputtering.

Next, a resist mask is formed on the metal film by exposure through a photomask and development. Gate lines and gate electrodes 31 are then formed by dry etching.

Next, SiN having a thickness of approximately 0.6 μm, for example, is deposited over the entire substrate by plasma CVD for forming gate insulating film 32. Next, a Si layer having a thickness of approximately 30 nm is deposited over the entire substrate by high-density plasma CVD for forming semiconductor film 33. A protective film material layer (e.g., SiN) having a thickness of approximately 150 nm is then formed over the entire substrate by plasma CVD for forming channel protective film 34.

Next, a resist for preserving the protective film material layer over the area corresponding to the channel region of semiconductor film 33 is patterned. Using the resist as a mask, etching and resist removal processes are performed to pattern the protective film material layer, forming channel protective film 34.

Next, an n⁺ semiconductor film 35 (e.g., n⁺ amorphous Si) and a metal film such as Ti are sequentially deposited to form an ohmic contact layer.

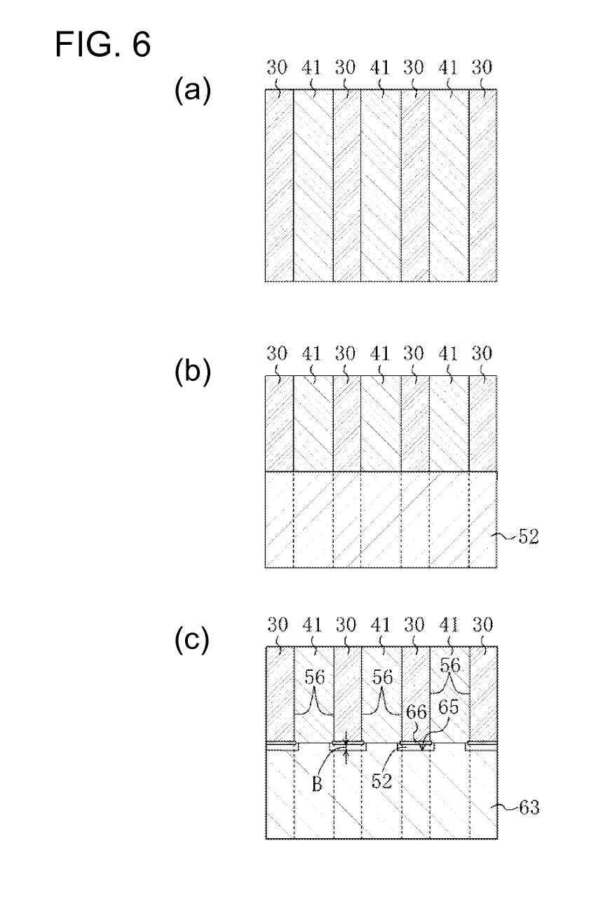

A photoresist is formed over the entire substrate, exposed to light through a mask, and subjected to developing process for resist patterning. The resist is used as an etching mask. For example, plasma dry etching is performed to form the source line, connection terminal 41 drawn from the source line to the substrate edge, source electrode 36, drain electrode 37, n⁺ semiconductor film 35, and semiconductor film 33. FIG. 6 (a) is a plan view of a connection terminal 41 formed in this process.

Next, as shown in FIG. 6 (b), interlayer insulating material 52 (e.g., SiN) is deposited over the entire substrate by plasma CVD to form a 0.2 μm thick film.

Next, a photomask 63 as shown in FIG. 6 (c) is prepared. Photomask 63 has, along its edge, a plurality of recesses 65 at equal intervals. Photomask 63 is disposed over interlayer insulating material 52, which is a subject of the processing, such that recesses 65 match the spaces between adjacent connection terminals 41. Recesses 65 are approximately rectangular. Each of the recesses 65 bridges across one side 56 of a connection terminal 41 and the adjacent side 56 of a neighboring connection terminal 41.

Photomask 63 has a rod portion 66 within each recess 65, wherein the rod portion 66 is apart from the base of the recess 65 by predetermined clearance B. Rod portion 66 is separate from recess 65 and bridges across one side 56 of a connection terminal 41 to the adjacent side 56 of a neighboring connection terminal 41. Clearance B between the base of the recess 65 and the rod portion 66 is set to be less than the resolution limit of the exposure device used for exposing interlayer insulating film 38 at a later process.

Next, interlayer insulating material 52 is exposed through photomask 63, followed by development. This results in interlayer insulating film 38 shown in FIG. 3 having contact holes for connection to thin film transistor 40 and an edge along which tips of connection terminal 41 are exposed.

Notches 42 corresponding to recesses 65 of photomask 63 are formed in interlayer insulating film 38 between neighboring connection terminals 41 and over certain portions of connection terminals 41. Stepped portion 46, comprising the first face 43, which is the bottom face of notch 42, and second face 44, which continues from the first face 43 through sloped face 45, is also formed at this time.

As described above, clearance B between the base of recess 65 and rod portion 66 is set to be less than the resolution limit of exposure device used for exposing interlayer insulating film 38. This means that the area on interlayer insulating film 38 in the recess 65 is not subjected to sufficient light exposure and development. As a result, stepped portion 46, having a lower face (the first face 43), is formed in the interlayer insulating film 38 along the edge, instead of a through hole in the edge of interlayer insulating film 38.

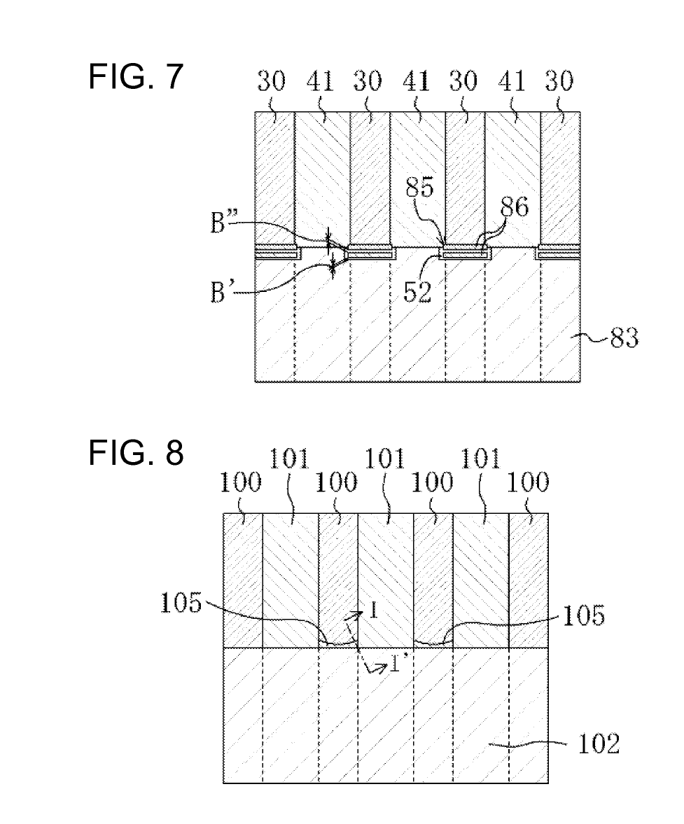

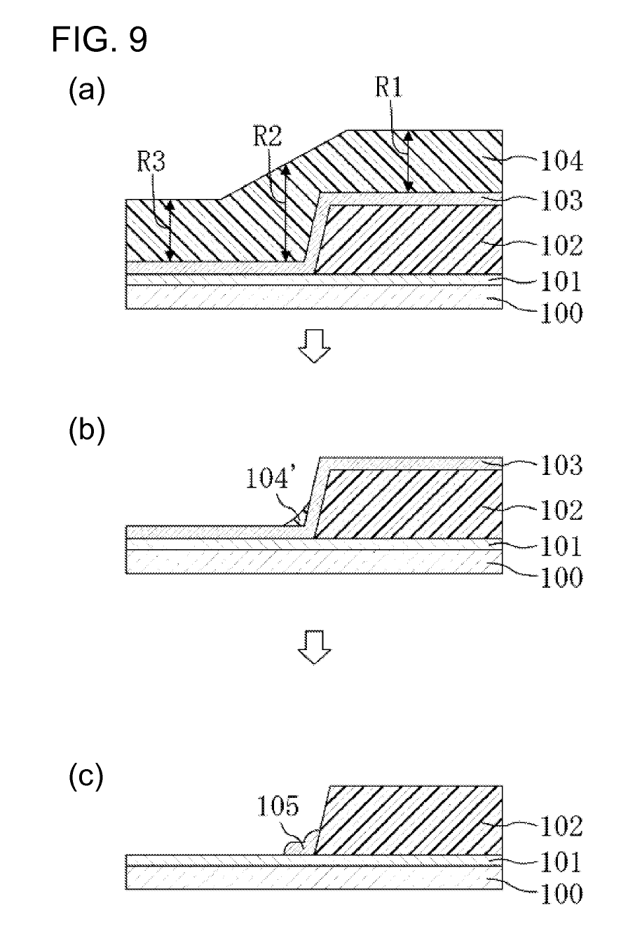

Photomask 63 may have other forms than that shown in FIG. 6 (c). For example, as shown in FIG. 7, photomask 83 may have two rod portions 86 disposed in parallel with each other within recess 85. In this case also, clearance B′ between the base of recess 85 of photomask 83 and rod portion 86 and clearance B″ between the two rod portions 86 are set to be less than the resolution limit of the exposure device used for exposure of interlayer insulating film 38.

Next, pixel electrode material ITO is deposited over the entire substrate by sputtering to form an approximately 0.1 μm thick film. A photosensitive resist is then formed over the entire substrate. Since the interlayer insulating film 38 has stepped portions 46 along the edge, the photosensitive resist forms a gentle slope along the stepped portion 46. Therefore, the extra thickness of photosensitive resist in the vicinity of the edge of interlayer insulating film 38 is minimized.

Next, the photosensitive resist is subjected to exposure and development, by which photosensitive resist is patterned over the region where the ITO is to be preserved. As described above, since the extra thickness of the photosensitive resist in the vicinity of the edge of interlayer insulating film 38 is minimized, no photosensitive resist residue remains near the edge of connection terminal 41.

Next, using the patterned photosensitive resist as a mask, the ITO is etched to form pixel electrode 39. As described above, since there is no photosensitive resist residue on the ITO, the material for pixel electrode, pixel electrode 39 is patterned over each connection terminal 41 precisely, leaving no residue of pixel electrode 39 between connection terminals 41.

Next, the photosensitive resist is removed, followed by polyimide application over the entire substrate to form alignment film 17. Thin film transistor substrate 13 is then completed.

Color filter substrate 14 is manufactured in the method described below. First, a glass substrate, which is the base of color filter substrate 14, is prepared. Over a certain region of the glass substrate, a black matrix is formed using metal such as Cr or a black resin. Next, over the glass substrate, red, green and blue color filters are formed using red photosensitive resin, green photosensitive resin, and blue photosensitive resin. Next, an opposite electrode is formed by sputtering a transparent conductive film such as ITO over the entire top surface of the glass substrate. Then, polyimide is applied over the opposite electrode to form an alignment film 27. Color filter substrate 14 is then completed.

Thin film transistor substrate 13 and color filter substrate 14, which are manufactured as described above, are bonded together, face to face, with spacers (not shown) in between by the sealing member 29. Liquid crystal display panel 11 is completed when liquid crystal is sealed in between the two substrates.

Next, polarizers 18 and 28 are installed on the respective sides of liquid crystal panel 11 in the direction of the panel thickness, followed by the installation of drive circuits and backlight 12. This completes liquid crystal display device 10.

(Operational Advantages)

Operational advantages of the embodiment of the present invention are described below. Liquid crystal display device 10 of the present invention has stepped portions 46 in interlayer insulating film 38 along its edge in the location corresponding to the spaces between adjacent connection terminals 41. When a photosensitive resist for pixel electrode material patterning is applied over the interlayer insulating film 38, the stepped portions 46 along the edge between adjacent connection terminals 41 allow the photosensitive resist to form a gentle slope. This minimizes the extra thickness of the photosensitive resist deposited in the vicinity of the edge of the interlayer insulating film 38, thereby successfully avoiding the formation of photosensitive resist residue near the edge of the interlayer insulating film 38 after the photosensitive resist removal process. In the absence of this photosensitive resist residue, no residue of pixel electrode 39 is left behind. This way, leakage current between adjacent connection terminals 41 is successfully prevented.

The rectangular shape of the first face 43 of stepped portion 46 allows the first face 43 (lower level face) to be wide and to be formed efficiently on interlayer insulating film 38 along the edge in locations corresponding to the spaces between adjacent connection terminals 41.

Although, in these embodiments, the display device is related to an LCD (liquid crystal display), the display device is not limited to LCD-related devices. The display device may be organic EL (organic electro luminescence), inorganic EL (inorganic electro luminescence), electrophoretic, PD (plasma display), PALC (plasma addressed liquid crystal display), FED (field emission display), or SED (surface-conduction electron-emitter display).

### Embodiments

On the thin film transistor substrate having the structure as described before, evaluation tests were conducted as follows to examine the relationship between the presence or absence of the photosensitive resist residue and shapes of stepped portions of the interlayer insulating film, which stepped portions correspond to the spaces between adjacent connection terminals.

### Embodiments

Interlayer insulating films 38 having the structure shown in FIG. 3 to FIG. 5 in the description of Embodiment 1 were prepared. The level difference between the first face 43 and the second face 44 of the stepped portion 46 was 0.2 to 2.5 μm, and the length (L) of the first face 43, which is in the extending direction of connection terminals 41, was 4.0 μm (Embodiment 1) or 8.0 μm (Embodiment 2).

Next, on the interlayer insulating films 38 of Embodiment 1 and Embodiment 2, a photosensitive resist was patterned in the manufacturing method described in the embodiment.

In each manufacturing process, connection terminal 41 was 0.495 μm in thickness, and interlayer insulating film 38 disposed on the entire substrate was 0.26 μm in thickness.

Next, for both Embodiment 1 and Embodiment 2, ITO as the pixel electrode material was deposited over the entire substrate by sputtering to form a 0.13 μm thick film. Then, a photosensitive resist was applied over the entire substrate.

Next, the photosensitive resist was subjected to exposure and development, by which the photosensitive resist was patterned over the region where ITO is to be preserved. For exposure treatment, three different exposure amounts were used (45, 50 or 60 mJ/cm²). Presence or absence of photosensitive resist residues was investigated by microscopic examination.

### Comparison Example

As a reference, a substrate having the same structure as the Embodiments, except that it was not subjected to the formation of notches and stepped portions in the interlayer insulating film as described in the embodiment, was prepared. Presence or absence of photosensitive resist residue was investigated by microscopic examination in the same manner.

(Test Results)

Table 1 shows the test results of the examples and the reference.

TABLE 1

| | Embodiment | Embodiment | Comparison |
|---|---|---|---|
| | 1 | 2 | example |
| L | 4 μm | 8 μm | |
| (Exposure amount) | | | |
| 45 mJ/cm² | ∘ | ∘ | x |
| 50 mJ/cm² | ∘ | ∘ | x |
| 60 mJ/cm² | ∘ | ∘ | ∘ |

∘: No resist residue present.
x: Resist residue existed and spanned the adjacent connection terminals.

As shown in Table 1, in the comparison example in which notches or stepped portions were not formed in the interlayer insulating film, resist residues remained and spanned the adjacent connection terminals when exposure amount was 45 mJ/cm² or 50 mJ/cm², while the residue was not left in Embodiment 1 and Embodiment 2.

The test results indicate that formation of notches and stepped portions in the interlayer insulating film is an effective measure to avoid formation of the resist residue. The test results also indicate that a length (L) of 4.0 μm in the extending direction of the connection terminal of the first face in the notch of the interlayer insulating film is adequate.

In Embodiment 2 where L was 8.0 μm, the formation of the resist residue was avoided more effectively than in Embodiment 1 where L was 4.0 μm. This finding indicates that the length L of the first face of the notch in the interlayer insulating film in the extending direction of the connection terminal is preferably longer.

### INDUSTRIAL APPLICABILITY

As described above, the present invention is useful for a display device and for a method for manufacturing the same.

### DESCRIPTION OF REFERENCE NUMERALS

10 Liquid crystal display device
13 Thin film transistor substrate
30 Glass substrate
38 Interlayer insulating film
39 Pixel electrode
41 Connection terminal
42 Notch
43 The first face (the bottom face of the notch)
44 The second face
45 Sloped face
46 Stepped portion
52 Interlayer insulating material
55 Sloped face
56 Side
65, 85 Recess
63, 83 Photomask
66, 86 Rod portion

1. A display device comprising an active matrix substrate having a plurality of switching elements arranged in a matrix and an opposite substrate located opposite to said active matrix substrate through a display medium layer, wherein said active matrix substrate comprises:
a plurality of connection terminals for sending drive signals to the switching elements, wherein the connection terminals are respectively electrically connected to, and led out from, the switching elements and are arranged in parallel with each other;
an interlayer insulating film disposed over the plurality of switching elements and over the plurality of connection terminals, wherein tips of the plurality of connection terminals along an edge of the interlayer insulating film are exposed; and
a pixel electrode disposed on said interlayer insulating film and on an exposed region of the plurality of connection terminals, the pixel electrode being electrically connected to said switching element through a contact hole formed in said interlayer insulating film,
wherein said interlayer insulating film has a notch with a bottom face at an end of a region corresponding to a space between the plurality of connection terminals, said interlayer insulating film having a stepped portion constituted of a first face constituting the bottom face of the notch, a second face, which is at a higher level than the first face, and a sloped face that continues from the first face to the second face.

2. The display device according to claim 1, wherein the first face of said interlayer insulating film is rectangular.

3. The display device according to claim 2, wherein the height difference between the first face and the second face is 0.2 to 2.5 μm.

4. The display device according to claim 2, wherein the length of the first face in an extending direction of said connection terminals is 4.0 μm or longer.

5. The display device according to claim 1, wherein said display medium comprises a liquid crystal material.

6. The display device according to claim 1, wherein said pixel electrode is made of indium tin oxide or indium zinc oxide.

7. The display device according to claim 1, wherein said switching element is a thin film transistor.

8. A manufacturing method for the display device having the active matrix substrate having a plurality of switching elements arranged in a matrix, and an opposite substrate that is located opposite to said active matrix substrate through a display medium layer, the method comprising the steps of:
preparing an insulating substrate for said active matrix substrate;
arranging a plurality of switching elements in matrix on the insulating substrate, and forming a plurality of connection terminals, which are arranged in parallel with each other and respectively electrically connected to, and led out from, the switching elements, for sending drive signals to the switching elements;
forming an interlayer insulating material over said insulating substrate on which said switching elements and said connection terminals are disposed;
forming an interlayer insulating film over the plurality of switching elements and over the plurality of connection terminals by subjecting said interlayer insulating material to exposure and development using a photomask having a plurality of recesses along an edge of the photomask, which recesses are arranged at a certain interval, wherein the interlayer insulating film has a contact hole leading to the switching elements, exposes tips of the plurality of connection terminals along an edge of the interlayer insulating film, and has a notch with a bottom face at an end of a region corresponding to a space between the plurality of connection terminals, said interlayer insulating film having a stepped portion constituted of a first face constituting the bottom face of the notch, a second face, which is at a higher level than the first face, and a sloped face, which continues from the first face to the second face;
forming an pixel electrode material over said insulating substrate on which said interlayer insulating film has been disposed;
disposing a photosensitive resist on said pixel electrode material and subjecting the resist to exposure and development; and
forming a pixel electrode on said interlayer insulating film and on an exposed region of the plurality of connection terminals, the pixel electrode being electrically connected to said switching element through said contact hole formed in said interlayer insulating film, by etching process in which said photosensitive resist is used as a mask.
